(19) United States
(12) Patent Application Publication
(10) Pub. No.: US 2007/0023166 A1
(43) Pub. Date: Feb. 1, 2007

(54) Heat-dissipating device and method

(75) Inventor: Ying Hao Hung, Taipei County (TW)

Correspondence Address: QUINTERO LAW OFFICE, 1617 BROADWAY, 3RD FLOOR, SANTA MONICA, CA, 90404, US

(73) Assignee: LITE-ON TECHNOLOGY CORPORATION, TAIPEI (TW)

(21) Appl. No.: 11/294,741

(22) Filed: Dec. 5, 2005

(30) Foreign Application Priority Data
Jul. 27, 2005 (TW) TW94125415

(51) Int. Cl. H05K 7/20

(52) U.S. Cl. 165/80.3; 165/121; 361/697

(57) ABSTRACT

The invention provides a heat-dissipating device and method. The heat-dissipating device comprises a transmitting device, at least a fin, and a fan. The transmitting device comprises a heat-dissipating channel and a passage. The passage comprises a converging intersection connecting to the heat-dissipating channel and the channel. The heat-dissipating method comprises dividing a air into a first airflow and a second airflow, and guiding the first airflow to pass through a fin while guiding the second airflow to converge into the first airflow and then passing through the fin together.

### BACKGROUND

The invention relates in general to a heat-dissipating device and method, and in particular to a heat-dissipating device and method for a computer.

Referring to FIG. 1, the heat-dissipating device 10 comprises a fan 11 and a transmitting device 12. The transmitting device 12 has a guide channel 13. A fin 14 (heat source) is installed in the guide channel 13. When the fan 11 operates, air is transmitted into the transmitting device 12 as shown by arrow A to provide a cooler airflow to the fin 14 for reducing temperature thereof.

FIGS. 1 and 2 show an air inlet 131 of the guide channel 13. An air flow is inducted via air inlet 131 to exhaust heat from the fin 14. The inducted air flow temperature is gradually raised from room temperature T₁ to T.

Newton's law of cooling is Q=hAΔT (Q is heat transfer rate; h is convection coefficient; A is convection area; ΔT=T_{f}−T; T_{f} is the fin temperature; T is the air temperature). If the curve of line L₀ in FIG. 2 becomes gentle, T will reduce to increase ΔT and Q. A gentler curve line L₀ of FIG. 2 can dissipate more heat from the fin 14.

### SUMMARY

Accordingly, the invention provides a heat-dissipating device and method. The heat-dissipating device comprises a transmitting device and a fan for drawing air. The transmitting device comprises a guide channel and a passage to adjoin the guide channel. Air in the passage enters the guide channel via a converging intersection. The step of the heat-dissipating method comprises dividing a air into a first airflow and a second airflow, guiding the first airflow to pass through a fin, and then guiding the second airflow to converge into the first airflow and then passing through the fin together.

### BRIEF DESCRIPTION OF THE DRAWINGS

The invention can be more fully understood by reading the subsequent detailed description and examples with references made to the accompanying drawings, wherein:

FIG. 1 is a schematic drawing of a conventional heat-dissipating device;

FIG. 2 is a relationship drawing of temperature and location of air in a conventional heat-dissipating device;

FIG. 3 is a schematic drawing of a heat-dissipating device;

FIG. 4 is a lateral drawing of a heat-dissipating device;

FIG. 5 is a relationship drawing of temperature and location of air in a heat-dissipating device;

FIG. 6 is a comparison drawing of FIG. 1 and FIG. 5; and

FIG. 7 is a flow chart of heat-dissipating method.

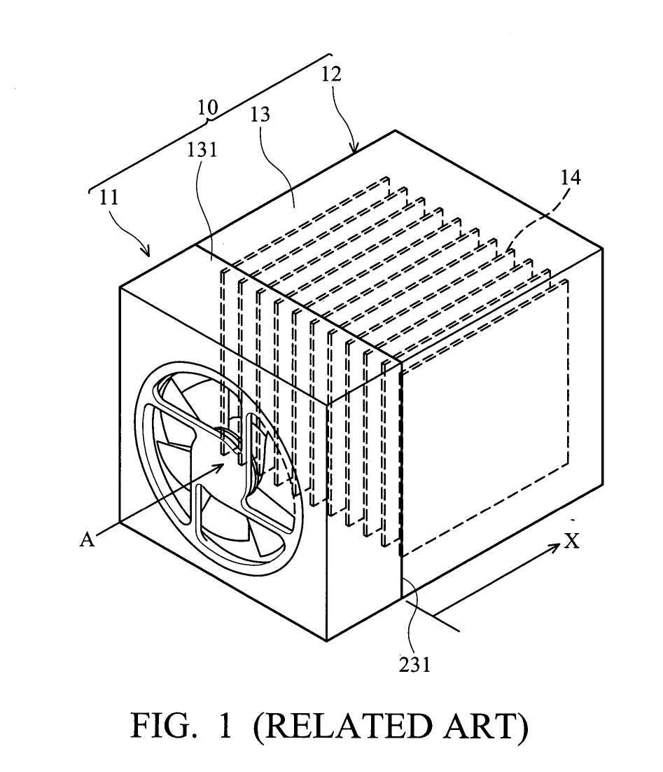

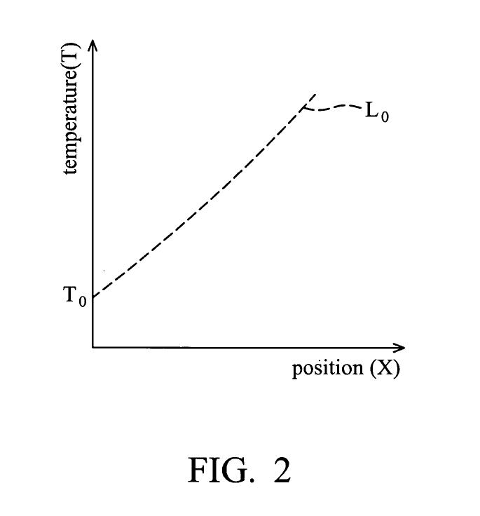

### DETAILED DESCRIPTION

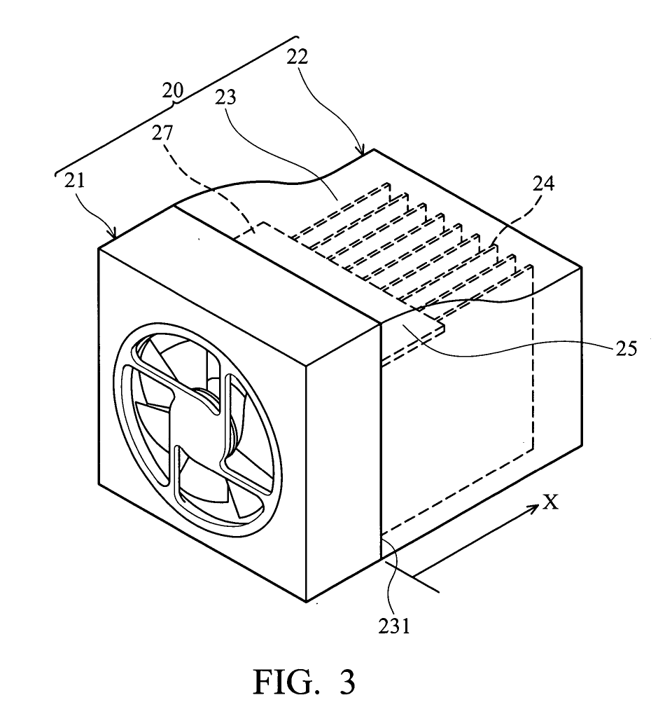

Referring to FIG. 3, a heat-dissipating device 20 comprises a fan 21 and a transmitting device 22. The transmitting device 22 comprises a guide channel 23 and a passage 25. A fin 24 in the guide channel 23 connects to electronic elements(not shown) of the electronic device to facilitate dissipation of heat from electronic elements via conduction. In this embodiment, the fin 24 is viewed as a heat source and has greater temperature.

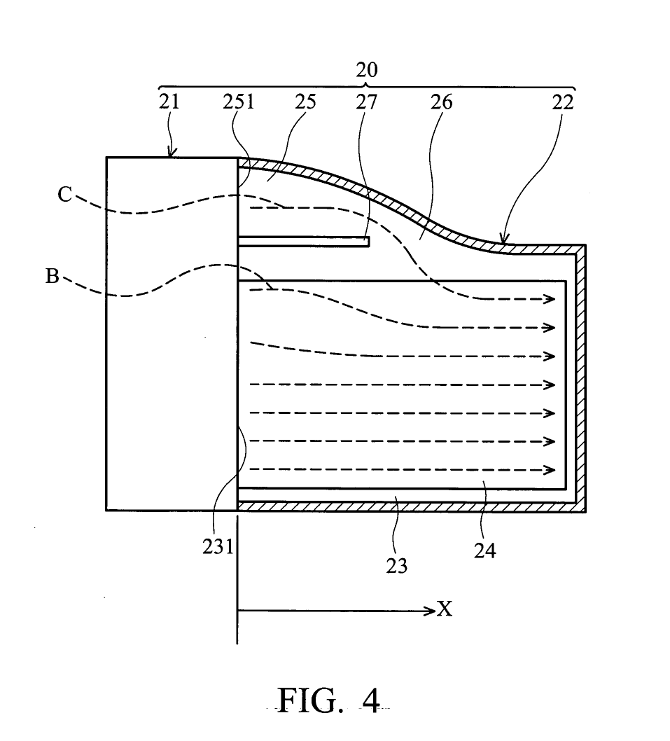

FIGS. 3 and 4 show that the guide channel 23 and passage 25 respectively have air inlets 231 and 251. The guide channel 23 and passage 25 are approximately separated via a partition 27 located therebetween. The guide channel 23 and passage 25 intersect at the converging intersection 26. The fan 21 draws outside air to separately enter the guide channel 23 and passage 25 as shown by arrows B and C. Air passing through air inlet 231 enters the guide channel 23. Air entering the passage 25 next to the guide channel 23 meets the air in the guide channel 23 at the converging intersection 26.

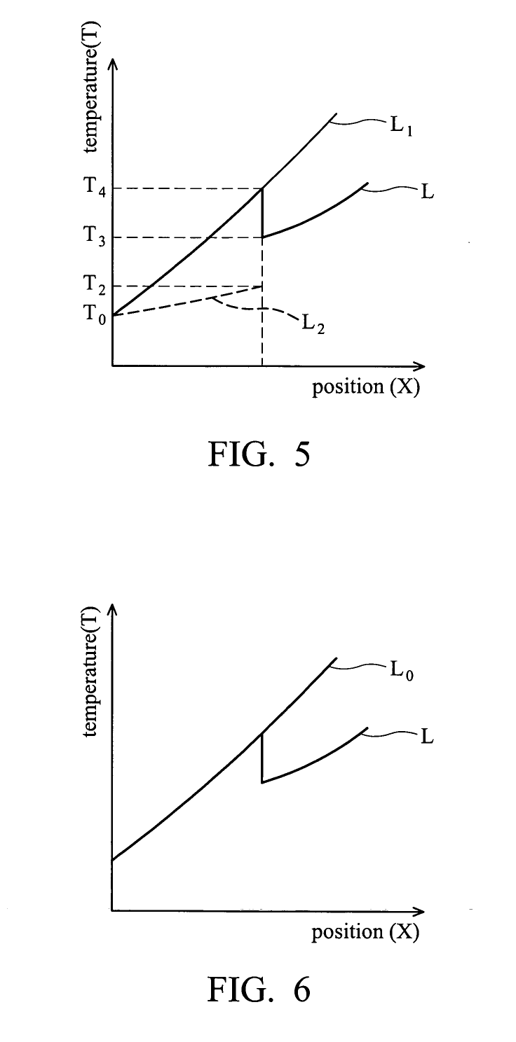

Referring to FIGS. 3, 4 and 5, FIG. 5 is a relationship drawing of location and temperature that airflow with arrow B entering the heat-dissipating device 20. Air is at room temperature T₀. After entering the air inlet 231 of the guide channel 23, air blows directly on the fin 24, raising the temperature of the air. Curved line L₂ represents the relationship between location and temperature of airflow entering the heat-dissipating device 20 as shown by arrow C. The partition 27 separates the passage 25 from the guide channel 23 in which the fin 24 is disposed, whereby airflow in the passage 25 is kept from the fin 24 (heat source). After outside air enters the heat-dissipating device 20 variation of air temperature in the passage 25 is gentler than in the guide channel 23. When arriving at the converging intersection 26, the air in the passage 25 meets air in the guide channel 23. Because air in the passage 25 is added in the guide channel 23, air temperature in the guide channel 23 decreases from T₄ to T₃. Newton's law of cooling is Q=hAΔT (Q is heat transfer rate; h is convection coefficient; A is convection area; ΔT=T_{f}−T; T_{f} is the fin temperature; T is the air temperature). Decrease of air temperature from T₄ to T₃ can increase ΔT and Q. The invention can dissipate more heat, increasing heat-dissipation efficiency.

Referring to FIGS. 4 and 6, the invention lowers air temperature in the guide channel 23 twice via the converging intersection 26. Newton's law of cooling is Q=hAΔT (Q is heat transfer rate; h is convection coefficient; A is convection area; ΔT=T_{f}−T; T_{f} is the fin temperature; T is the air temperature). Compared L₀ with L, the heat-dissipating device 20 provides air in the guide channel 23 lower temperature twice to decrease T and increase ΔT and Q. The invention can dissipates more heat, increasing heat-dissipation efficiency.

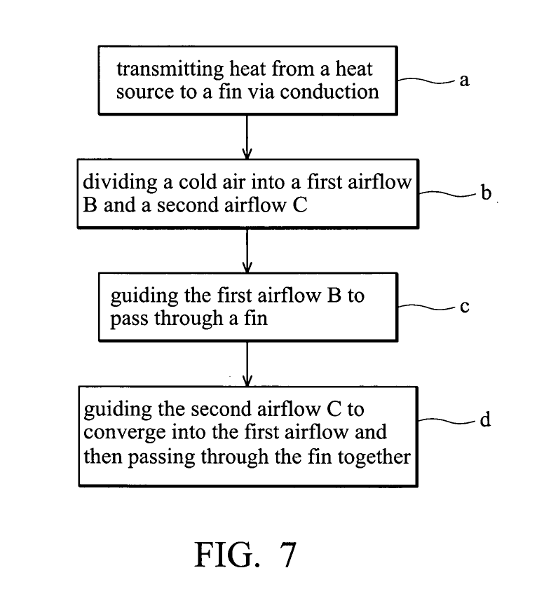

FIG. 7 discloses a heat-dissipating method. The steps of the heat-dissipating method comprise transmitting heat from a heat source to a fin via heat conduction, dividing a air into a first airflow B and a second airflow C, guiding the first airflow B to pass through a fin, and guiding the second airflow C to converge into the first airflow to pass through the fin together. In the method, air temperature in the passage 25 is lower than in the guide channel 23.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat-dissipating device, comprising:
a transmitting device comprising a guide channel and a passage, the passage comprising a converging intersection connecting to the guide channel;
at least a fin installed in the guide channel; and
a fan conveying respectively air into the guide channel and the passage;
wherein air in the passage enters the guide channel via the converging intersection.

2. The heat-dissipating device as claimed in claim 1, wherein the guide channel comprises an air inlet not connected to the converging intersection.

3. The heat-dissipating device as claimed in claim 2, wherein the transmitting device is one piece and further comprises a partition to separate the guide channel and the passage.

4. A heat-dissipating method, comprising:
dividing a air into a first airflow and a second airflow;
guiding the first airflow to pass through a fin;
guiding the second airflow to converge into the first airflow and then pass through the fin together.

5. The heat-dissipating method as claimed in claim 2, further comprising transmitting heat from a heat source to the fin via heat conduction.
